(19) United States
(12) Patent Application Publication
(10) Pub. No.: US 2008/0207006 A1
(43) Pub. Date: Aug. 28, 2008

(54) PROCESS FOR FABRICATING AN INTEGRATED CIRCUIT

(76) Inventors: James Scott Martin, Garland, TX (US); John P. Campbell, Dallas, TX (US); Phuong-Lan Tran, Las Colinas, TX (US); Alfred J. Griffin, Dallas, TX (US); Maxwell Walthour Lippitt, Rockwall, TX (US)

Correspondence Address: TEXAS INSTRUMENTS INCORPORATED, P O BOX 655474, M/S 3999, DALLAS, TX, 75265, US

(21) Appl. No.: 11/680,340

(22) Filed: Feb. 28, 2007

(51) Int. Cl. H01L 21/469

(52) U.S. Cl. 438/763; 427/255.7; 427/337

(57) ABSTRACT

The present disclosure is directed to a process for plasma treating a film comprising titanium, nitrogen and impurities on a substrate. The process comprises forming a plasma of nitrogen gas and hydrogen gas, the flow ratio of hydrogen gas to nitrogen gas ranging from about 0.01 to about 0.7. The film is contacted with the plasma for a time sufficient to reduce the concentration of impurities in the film.

### DESCRIPTION OF THE DISCLOSURE

1. Field of the Disclosure

The present disclosure is directed to a process for manufacturing integrated circuits, and more specifically, to a process for plasma treating MOCVD layers.

2. Background of the Disclosure

Titanium nitride (TiN) films are widely used in integrated circuit manufacture. Titanium nitride has become an integral part of advanced metallization schemes for many ultra large scale integrated circuit (ULSI) applications. It is used, for example, as a diffusion barrier layer against junction spiking for aluminum contacts to silicon. In addition, TiN can serve as a barrier layer. For, example, it is well known to employ TiN between tungsten metal plugs and titanium adhesion layers. The TiN acts as a barrier layer to fluorine during the chemical vapor deposition (CVD) of tungsten, and thereby reduces the corrosive effects of fluorine that would otherwise occur on the titanium layer.

Metal oxide chemical vapor deposition (MOCVD) is a well known method for depositing TiN films. During MOCVD of TiN films, an organic TiN precursor gas is generally flowed into the reactor chamber at a temperature sufficient to deposit a TiN film onto the subtrate. However, the TiN film deposited by this method may contain relatively higher carbon and/or oxygen content than does TiN thin films produced by certain other methods. The relatively higher carbon content tends to reduce the density of the TiN thin film. The reduction in film density commensurately reduces the effectiveness of the TiN thin film as a barrier layer.

To reduce the amount of carbon in a TiN thin film deposited by MOCVD, a plasma treatment can be carried out using scavenger gases, such as a nitrogen and hydrogen mixture. This plasma treatment removes the carbon from the TiN thin film, and increases the film density.

As will be discussed in greater detail below, the inventors of the present disclosure have unexpectedly discovered that the hydrogen plasma treatment may cause certain problems in the metallization structure. For example, the hydrogen plasma treatment has been found to at least partially be responsible for blistering of aluminum metal lines, which sometimes occurs during high temperature operations, such as sintering, near vias in which TiN barrier layers are formed. Such blistering is undesirable, as it can cause deformation and increase resistance of the metal lines. For these reasons, improved processing of metal barrier layers, such as titanium nitride, is desired.

### SUMMARY OF THE DISCLOSURE

In accordance with the disclosure, an embodiment is disclosed herein that is directed to a process for fabricating an integrated circuit on a substrate. The process includes forming an aluminum metallization structure on the substrate and forming an interlevel dielectric over the aluminum metallization structure. A contact hole is formed in the interlevel diectric. A conductive layer is deposited in the contact hole. At least a portion of a barrier layer is deposited comprising titanium, nitrogen, and impurities on the conductive layer by MOCVD. A plasma is formed from a scavenging gas comprising hydrogen gas and one or more additional gases, the flow ratio of hydrogen gas to the one or more additional gases ranges from about 0.01 to about 0.7. The barrier layer is contacted with the scavenging gas plasma for a time sufficient to reduce the concentration of impurities in the barrier layer. A tungsten plug in then formed in the contact hole. A sintering process is performed on the integrated circuit at a desired sinter temperature, the sintering process being performed subsequent to forming the tungsten plug.

Another embodiment of the present disclosure is directed to a process for forming a TiN film on a substrate. The process comprises introducing the substrate into a deposition chamber. A carbon containing precursor gas is introduced into the deposition chamber and a TiNCO film is deposited on the substrate by decomposing the carbon containing precursor gas. A plasma is formed from the hydrogen gas and nitrogen gas, the flow ratio of hydrogen gas to nitrogen gas ranging from about 0.01 to about 0.7. The TiNCO film is contacted with the plasma for a time sufficient to reduce the carbon and oxygen content in the TiNCO film.

Another embodiment of the present disclosure is directed to a process for plasma treating a film comprising titanium, nitrogen and impurities on a substrate. The process comprises forming a plasma of nitrogen gas and hydrogen gas, the flow ratio of hydrogen gas to nitrogen gas ranging from about 0.01 to about 0.7. The film is contacted with the plasma for a time sufficient to reduce the concentration of impurities in the film.

Additional embodiments and advantages of the disclosure will be set forth in part in the description which follows, and can be learned by practice of the disclosure. It is to be understood that both the foregoing general description and the following detailed description are exemplary and explanatory only and are not restrictive of the disclosure, as claimed.

The accompanying drawings, which are incorporated in and constitute a part of this specification, illustrate several embodiments of the disclosure and, together with the description, serve to explain the principles of the disclosure.

### BRIEF DESCRIPTION OF THE DRAWINGS

FIG. 1 illustrates a flow chart of a process for depositing a barrier layer comprising titanium nitride on a substrate, according to an embodiment of the present disclosure.

FIGS. 2A to 2C illustrate a process for filling a via, including depositing a barrier layer comprising titanium nitride, according to an embodiment of the present disclosure.

FIG. 3 illustrates one example showing the correlation found between reduced blistering and lower hydrogen gas to nitrogen gas ratios, according to the present disclosure.

### DESCRIPTION OF THE EMBODIMENTS

Reference will now be made in detail to various exemplary embodiments of the present disclosure, examples of which are illustrated in the accompanying drawings. Wherever possible, the same reference numbers will be used throughout the drawings to refer to the same or like parts.

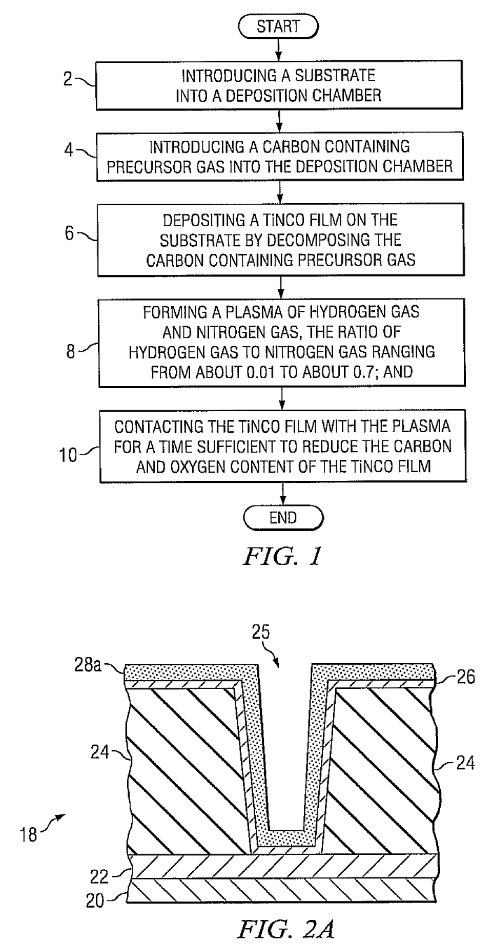

FIG. 1 illustrates a flow chart of a process for depositing a barrier layer comprising titanium nitride on a substrate, according to an embodiment of the present disclosure. Initially, a substrate is introduced into a deposition chamber, as illustrated at 2. Any suitable substrate on which it may be desirable to from a barrier layer comprising titanium nitride may be employed. The substrate may include, for example, a partially formed integrated circuit device.

A carbon containing precursor gas is introduced into the deposition chamber and a TiNCO film is deposited on the substrate by decomposing the carbon containing precursor gas, as illustrated at 4 and 6. The film can be deposited by any suitable method, such as by metal organic chemical vapor deposition (MOCVD).

After forming the TiNCO film, a plasma of hydrogen gas and one or more additional gases is formed, as illustrated at 8. In an embodiment, the flow ratio of hydrogen gas to nitrogen gas ranges from about 0.01 to about 0.7. In other embodiments, the ratio can range from about 0.05 to about 0.5, such as from about 0.05 to about 0.2. In another exemplary embodiment, the flow ratio of hydrogen gas to nitrogen gas can be approximately 1:9. The TiNCO film is then contacted with the plasma for a time sufficient to reduce the film's carbon and oxygen content, as illustrated in 10.

It has been found that by employing a hydrogen gas flow ratio within the disclosed ranges during the plasma treatment, reduced blistering of aluminum lines formed in proximity to the titanium layer occurs compared with processes in which relatively higher flow ratios of the hydrogen are employed. While the mechanism for the reduced blistering is not entirely understood, it is believed that processes which employ a relatively high concentration of hydrogen in the plasma treatment process result in relatively high concentrations of hydrogen being incorporated into the TiN films. During subsequent high temperature processes, such as sintering, the hydrogen diffuses out of the films into surrounding aluminum metal structures, thereby causing the blistering.

One potential approach to remedy the solution is to employ lower temperature processing subsequent to the plasma treatment. However, this may have detrimental effects on the overall electrical properties of the devices. This is because the high temperature sinter process, which may be performed at temperatures of about 400° C. or above, helps to improve the electrical properties of the device active regions. In some embodiments, if the sinter operation is employed at lower temperatures of less than 400° C., the electrical properties of the active regions may not be improved as much as if the higher temperatures are used. For some devices, improvement in electrical properties can be seen at temperatures significantly higher than 400° C., as will be discussed in greater detail below. The inventors of the present disclosure have discovered that blistering of the aluminum can be reduced by reducing the flow ratio of hydrogen relative to the other gases in the plasma treatment, while still allowing for higher sinter temperatures, and the resulting improved electrical properties.

Blistering can also be reduced by eliminated hydrogen from the plasma treatment altogether. However, not employing any hydrogen results in increased carbon content, and possibly increased oxygen content, of the TiN film. The increased carbon and oxygen content can undesirably reduce conductivity of the TiN film, and result in increased contact resistance and decreased via reliability. Thus, by employing hydrogen at reduced flow ratios over conventional plasma treating processes, the inventors have discovered that a TiN film having sufficiently reduced carbon content can be achieved while reducing, and possibly eliminating, the blistering problems.

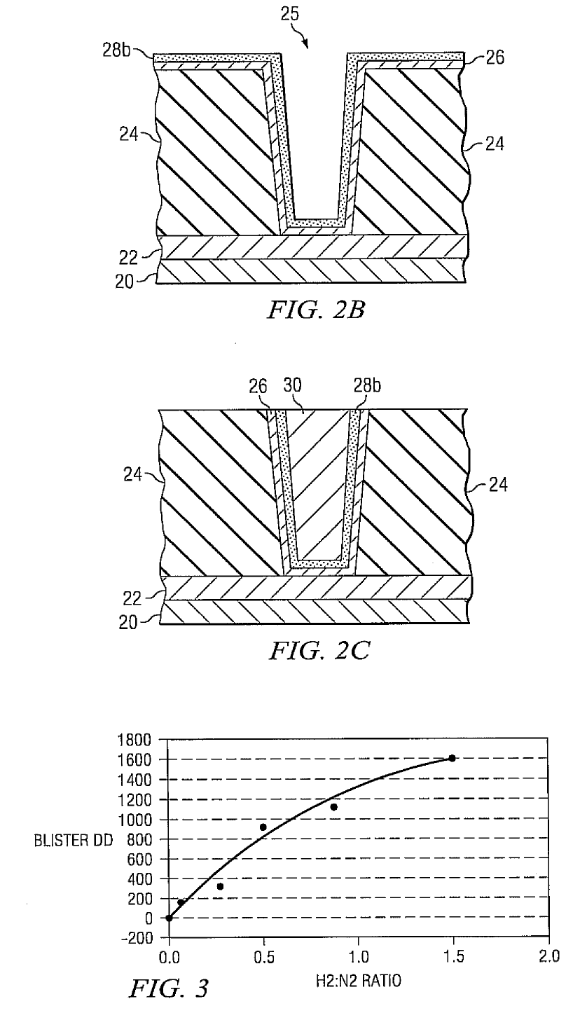

An embodiment of the present disclosure will now be discussed with reference to FIGS. 2A to 2C. FIG. 2A illustrates a partially formed integrated circuit 18 having a metallization layer 20, which may be any metal structure comprising aluminum. As would be readily understood by one of ordinary skill in the art, in addition to metallization layer 20, the integrated circuit 18 may include, for example, a substrate comprising various devices, such as transistors, formed on the substrate, as well as other layers and structures, which are not illustrated. For example, metallization layer 20 may be part of a metal interconnect structure for metal levels 1 or higher in an integrated circuit, as is well known in the art. In one embodiment, the metal interconnect can also include one or more other conductive layers 22, such as titanium and/or titanium nitride layers. Suitable processes for forming layers 20 and 22 are well known in the art.

An interlevel dielectric (ILD) structure 24 is formed over metallization layer 20. ILD structure 24 may be any suitable ILD structure made by any suitable process known in the art. While only a single dielectric layer is shown, ILD structure 24 may include multiple dielectric layers. A via hole 25 is formed in the ILD structure 24. Any suitable process for forming via hole 25 may be used, including etching processes that are well known in the art.

A conductive layer 26 is formed in via hole 25. Conductive layer 26 may include any suitable material, such as titanium, a titanium alloy, tantalum or a tantalum alloy. In one embodiment, the conductive layer is titanium formed by a standard physical vapor deposition (PVD) technique, such as ionized metal plasma physical vapor deposition (IMP PVD). Such PVD techniques are well known in the art.

A TiNCO layer 28a is then formed by a metal organic chemical vapor deposition (MOCVD) process. Any suitable MOCVD process may be employed. In one embodiment, the partially formed integrated circuit 18 is positioned in a chemical vapor deposition reactor. An organic precursor containing titanium and nitrogen is then flowed into the deposition chamber and the wafer is heated to a desired deposition temperature, such as, for example, 350° C. to 450° C. In one embodiment, the chamber is heated to approximately 435° C., although the wafer temperature may be somewhat lower than this. An example of a suitable organic precursor is tetrakisdimethyl-aminotitanium (TDMAT), although other organic precursors may also be employed. Other gases, such as nitrogen, helium or other carrier gases may also be flowed into the deposition reactor along with the organic precursor to achieve a desired flow rate, as is well known in the art. Under suitable flow conditions, a layer 28a of TiNCO is thereby deposited on the conductive layer 26 to a desired thickness. The layer comprises Ti and nitrogen, which may be in the form of TiN, as well as other impurities, such as carbon, hydrogen and/or oxygen.

Following deposition of TiNCO layer 28a, the TiNCO deposition gases are removed from the chamber and plasma treatment is carried out. In one embodiment, the plasma treatment gases, such as hydrogen gas (H₂) and nitrogen gas (N₂), are flowed through the deposition chamber and the plasma is formed. Any suitable method for forming the plasma can be employed, such as radio frequency plasma, electron cyclotron resonance plasma, microwave plasma or other methods well known in the art. Gas flows may be adjusted to achieve the desired gas ratios, flow rates and pressures inside the reactor. In an embodiment, the flow ratio of hydrogen gas to nitrogen gas ranges from about 0.01 to about 0.7. In other embodiments, the ratio can range from about 0.05 to about 0.5, such as from about 0.05 to about 0.2. Example flow rates for hydrogen gas may range from about 10 SCCM to about 500 SCCM; and nitrogen gas flow rates may range from about 100 SCCM to about 2000 SCCM. In one embodiment, the flow ratio of hydrogen gas to nitrogen gas can be approximately 1:9; the flow rate for hydrogen being about 100 SCCM and the flow rate for nitrogen being about 900 SCCM. The pressure inside the reactor may depend on the type of reactor employed, as well as other factors. Example pressures may range from about 0.1 torr to about 10 torr. In one embodiment, the reactor pressure may be about 0.8 torr. The plasma treatment is carried out for a time sufficient to remove the desired amount of carbon and other impurities form TiNCO layer 28a. For example, the plasma treatment may be carried out for a period of time ranging from about 10 seconds to about 100 seconds, such as about 35 seconds.

FIG. 2B illustrates the resulting titanium nitride layer 28b after plasma treatment has occurred. As seen from comparing layer 28a in FIG. 2A and layer 28b in FIG. 2B, the plasma treatment reduces the thickness of the TiNCO layer 28a. Layer 28b has a reduced concentration of carbon, and other impurities, such as hydrogen and oxygen, compared with layer 28a. This results in improved conductivity and barrier properties of layer 28b.

The resulting thickness of TiN layer 28b may be any desired thickness. For example, in one embodiment layer 28b may range from about 10 angstroms to about 100 angstoms in thickness. In some embodiments, it may be desired to form the TiN layer using multiple deposition and plasma treatment processes. It has been found that by depositing thinner layers between each plasma treatment, the carbon content of the TiNCO film can be more effectively reduced using the lower hydrogen to nitrogen ratios of the present disclosure. Thus, in one embodiment, a plurality of relatively thin layers which each result, after plasma treatment, in about a 25 angstrom film or less are consecutively deposited in order to provide a film of a desired thickness. For example, in an exemplary embodiment where the total thickness of layer 28b is to be about 50 angstroms, a first TiNCO layer 28a may be deposited and a plasma treatment is carried out to achieve a first desired thickness, such as about 25 angstroms. The process is then repeated by depositing a second TiNCO layer and performing a second plasma treatment to achieve a film having the total thickness of about 50 angstroms. In other embodiments, the total film thickness of layer 28b may be achieved by repeating the deposition and plasma treatment processes any number of times, such as three, four or more times.

Referring now to FIG. 2C, a conductive material is deposited over TiN layer 28b to fill the via 25. A portion of the conductive fill material is then removed, along with portions of conductive layer 26 and TiN layer 28b, to thereby form a conductive plug 30. In one embodiment, the conductive fill material is tungsten. The tungsten plug 30 can be formed by any suitable method. In one embodiment, tungsten plug 30 can be formed by a chemical vapor deposition process using, for example, tungsten hexafluoride (WF₆), silane and hydrogen gas at deposition temperatures ranging from about 350° C. to about 450° C. The reactor employed for depositing the tungsten can be any suitable CVD reactor, such as an Applied Materials CENTURA® 5200 equipped with a 200 mm WXZ™ Reactor. Following deposition of the tungsten, the excess tungsten and portions of conductive layer 26 and TiN layer 28b are removed from over the via by any suitable process, such as a chemical mechanical polishing (CMP) process. Such CMP processes are well known in the art.

While not intending to be bound by any particular theory, it is believed that fluorine from the tungsten hexafluoride process may worsen the blistering of the aluminum, discussed above. However, the use of the relatively low amounts of hydrogen employed in the processes of the present disclosure appears to reduce the blistering problem even when a tungsten hexafluoride process is used.

After formation of plug 30, further processing can be carried out to complete the integrated circuit device. This may include formation of additional standard metallization structures. For example, additional metal levels comprising an aluminum layer (not shown) can be deposited over the tungsten plug to form the next metal level. If desired, a titanium layer and/or titanium nitride layer may be formed over the aluminum, similarly as with layers 20 and 22 of FIG. 2A. Additional interlevel dielectrics may also be deposited between any additional metal levels that are formed, as is well known in the art.

Prior to final passivation of the wafer, a sinter process can be performed at temperatures ranging from about 400° C. to temperatures just below which the aluminum would be compromised. For example, the sinter process may occur at temperatures ranging from about 400° C. to about 450° C., such as about 425° C. to about 450° C. In one embodiment, the sinter process is carried out in a two step process involving: a first sinter in a hydrogen and nitrogen gas environment at temperatures ranging from about 400° C. to about 450° C. for a time ranging from about 5 to about 20 minutes; and a second sinter in a hydrogen environment at temperatures ranging from about 400° C. to about 450° C. for a time ranging from about 10 to about 30 minutes. In one exemplary embodiment, one or both of the sinter steps are carried out at a temperature of about 400° C. In another embodiment, one or both of the sinter steps are carried out at a temperature of about 435° C. Flow rates of the gases may vary depending on the sinter tool used and the desired pressures and flow regime in the sinter tool.

Following the sinter process, a protective coat, or passivation layer, is deposited on the wafer. Techniques for forming such a protective coat are well known in the art. Following deposition of the protective coat, a protective coat anneal (PO anneal) is carried out at a temperature of about 400° C. for a time ranging from about 15 to about 45 minutes. Example process parameters for both the sinter and anneal is shown in Table I below. The example processes are shown as being carried out in a TEL-alpha 858 furnace, available from Tokyo Electron, LTD, although any suitable furnace may be employed.

TABLE I

| | | | | H2 | N2 |
|---|---|---|---|---|---|
| | Tool | Temp (° C.) | Time (min) | (sccm) | (sccm) |
| Sinter, step 1 | TEL-alpha | 400–435 | 10 | 4000 | 6000 |
| | 858 | | | | |
| Sinter, step 2 | TEL-alpha | 400–435 | 20 | H2-only | 0 |
| | 858 | | | | |
| PO Anneal | TEL-alpha | 400 | 30 | 0 | N2 only |
| | 858 | | | | |

In some embodiments, the sinter process described above can result in improved device performance when a sinter temperature above about 425° C., such as a temperature of about 435° C., is employed, relative to device performance that would result if a sinter temperature of about 400° C. was employed. This improvement may occur, for example, in devices where large areas of interconnect metal reside directly above the transistors, or for high power or analog devices. In certain embodiments, temperatures of about 400° C. can be used to achieve the desired improvement in device performance, but only at the expense of longer (and more costly) sinter times.

Specific device parameters which may improve with the higher sinter temperatures include electrical properties of the device active regions, such as, for example: Rdson (the drain-source resistance with the device “on”); and Idlin ratio mismatch (which is a measure of the ratio of drain current/drain voltage for NMOS and PMOS devices).

FIG. 3 illustrates one example showing the correlation found between reduced blistering and lower hydrogen gas to nitrogen gas ratios. In FIG. 3, the vertical axis shows the number of blistering defects per square centimeter; and the horizontal axis shows the hydrogen gas to nitrogen gas ratio. As seen from FIG. 3, the number of blistering defects is relatively high (about 1600 per square centimeter) at a hydrogen to nitrogen gas ratio of 1.5, which is a standard ratio employed in conventional processes. However, as hydrogen to nitrogen ratios are reduced to below about 1, the number of defects is significantly reduced.

For the purposes of this specification and appended claims, unless otherwise indicated, all numbers expressing quantities, percentages or proportions, and other numerical values used in the specification and claims, are to be understood as being modified in all instances by the term “about.” Accordingly, unless indicated to the contrary, the numerical parameters set forth in the following specification and attached claims are approximations that can vary depending upon the desired properties sought to be obtained by the present disclosure. At the very least, and not as an attempt to limit the application of the doctrine of equivalents to the scope of the claims, each numerical parameter should at least be construed in light of the number of reported significant digits and by applying ordinary rounding techniques.

It is noted that, as used in this specification and the appended claims, the singular forms “a,” “an,” and “the,” include plural referents unless expressly and unequivocally limited to one referent. Thus, for example, reference to “an acid” includes two or more different acids. As used herein, the term “include” and its grammatical variants are intended to be non-limiting, such that recitation of items in a list is not to the exclusion of other like items that can be substituted or added to the listed items.

While particular embodiments have been described, alternatives, modifications, variations, improvements, and substantial equivalents that are or can be presently unforeseen can arise to applicants or others skilled in the art. Accordingly, the appended claims as filed and as they can be amended are intended to embrace all such alternatives, modifications variations, improvements, and substantial equivalents.

What is claimed is:

1. A process for fabricating an integrated circuit on a substrate, comprising:
a. forming an aluminum metallization structure on the substrate;
b. forming an interlevel dielectric over the aluminum metallization structure;
c. forming a contact hole in the interlevel diectric;
d. depositing a conductive layer in the contact hole;
e. depositing at least a portion of a barrier layer comprising titanium, nitrogen, and impurities on the conductive layer by MOCVD;
f. forming a plasma from scavenging gas comprising hydrogen gas and one or more additional gases, the flow ratio of hydrogen gas to the one or more additional gases ranging from about 0.01 to about 0.7;
g. contacting the barrier layer with the scavenging gas plasma for a time sufficient to reduce the concentration of impurities in the barrier film;
h. forming a tungsten plug in the contact hole; and
i. performing a sintering process on the integrated circuit at a desired sinter temperature, the sintering process being performed subsequent to forming the tungsten plug.

2. The process of claim 1, wherein the at least one additional gas is nitrogen gas.

3. The process of claim 1, wherein the flow ratio of hydrogen gas to the one or more additional gases ranges from about 0.05 to about 0.5.

4. The process of claim 1, wherein the flow ratio of hydrogen gas to the one or more additional gases ranges from about 0.05 to about 0.2.

5. The process of claim 1, wherein the flow ratio of hydrogen gas to the one or more additional gases is about 1:9.

6. The process of claim 1, wherein the tungsten plug is formed using a fluorine containing precursor gas.

7. The process of claim 6, wherein the fluorine containing precursor gas is WF₆.

8. The process of claim 1, further comprising repeating (e) (f) and (g) until the barrier film is a desired thickness.

9. The process of claim 1, wherein the sinter temperature is about 400° C. or above.

10. The process of claim 1, wherein the sinter temperature ranges from about 425° C. to about 450° C.

11. A process for forming a TiN film on a substrate, comprising:
a. introducing the substrate into a deposition chamber;
b. introducing a carbon containing precursor gas into the deposition chamber;
c. depositing a TiNCO film on the substrate by decomposing the carbon containing precursor gas;
d. forming a plasma of a hydrogen gas and nitrogen gas, the flow ratio of hydrogen gas to nitrogen gas ranging from about 0.01 to about 0.7; and
e. contacting the TiNCO film with the plasma for a time sufficient to reduce the carbon and oxygen content in the TiNCO film.

12. The process of claim 11, wherein the flow ratio of hydrogen gas to the nitrogen gas ranges from about 0.05 to about 0.5.

13. The process of claim 11, wherein the flow ratio of hydrogen gas to the nitrogen gas ranges from about 0.05 to about 0.2.

14. The process of claim 11, wherein the flow ratio of hydrogen gas to the nitrogen gas is about 1:9.

15. The process of claim 11, further comprising repeating (b) to (e) until the barrier film is a desired thickness.

16. The process of claim 15, wherein each repetition of steps (b) to (e) results in a layer having a thickness of about 25 angstroms or less.

17. A process for plasma treating a film comprising titanium, nitrogen and impurities on a substrate, the process comprising:
a. forming a plasma of nitrogen gas and hydrogen gas, the flow ratio of hydrogen gas to nitrogen gas ranging from about 0.01 to about 0.7; and
b. contacting the film with the plasma for a time sufficient to reduce the concentration of impurities in the film.

18. The process of claim 17, wherein the flow ratio of hydrogen gas to nitrogen gas ranges from about 0.05 to about 0.5.

19. The process of claim 17, wherein the flow ratio of hydrogen gas to nitrogen gas ranges from about 0.05 to about 0.2.

20. The process of claim 17, wherein the flow ratio of hydrogen gas to nitrogen gas is about 1:9.
